(19) United States
(12) Patent Application Publication
(10) Pub. No.: US 2025/0347003 A1
(43) Pub. Date: Nov. 13, 2025

(54) DUPLEX NANOCOMPOSITE COATING FORMED IN A SINGLE PHYSICAL VAPOR DEPOSITION DEVICE

(71) Applicant: Southwest Research Institute, San Antonio, TX (US)

(72) Inventor: Jianliang LIN, Helotes, TX (US)

(21) Appl. No.: 19/194,266

(22) Filed: Apr. 30, 2025

Related U.S. Application Data
(60) Provisional application No. 63/644,554, filed on May 9, 2024.

(51) Int. Cl. C23C 28/04; C23C 8/24; C23C 14/06; C23C 14/35

(52) U.S. Cl. CPC C23C 28/04; C23C 8/24; C23C 14/0641; C23C 14/354

(57) ABSTRACT

A method of coating a metal part in a single physical vapor deposition device which comprises placing a metal part having a surface into a single physical vapor deposition device comprising a plasma-enhanced magnetron sputtering (PEMS) apparatus. This is followed by nitriding the metal part surface and then depositing a Ti—Si—C—N nanocomposite coating.

### FIELD

The present invention is directed at a duplex nanocomposite coating. The coating is produced by forming a plasma nitriding layer followed by formation of a Ti—Si—C—N nanocomposite coating layer, where the nitriding and nanocomposite coating are applied in a single physical vapor deposition device.

### BACKGROUND

U.S. Pat. No. 9,523,146, entitled Ti—Si—C—N Piston Ring Coatings, describes a piston ring and method for forming a Ti—Si—C—N coating. The deposited coating exhibits a thickness in the range of 10.0 micrometers to 20.0 micrometers and a coefficient of friction of less than 0.15 and a wear rate of less than 10×10⁻⁶ nm³/N/m. The deposited Ti—Si—C—N coating includes nanocrystalline phases in an amorphous matrix.

U.S. Publication No. 2024/0093351, entitled Variable Hardness Nanocomposite Coating, describes a variable hardness nanocomposite coating and method for its production. The variable hardness coating can be applied as a single layer on metallic engine components that require a break-in to achieve physical mating of interacting surfaces thereby reducing friction and optimizing engine performance. The single layer nanocomposite coating has a relatively higher carbon content and lower hardness at the surface region and a relatively lower carbon content and relatively higher hardness region as one proceeds towards a surface of the metal component being coated.

### SUMMARY

A method of coating a metal part in a single physical vapor deposition device which comprises placing a metal part having a surface into a single physical vapor deposition device comprising a plasma-enhanced magnetron sputtering (PEMS) apparatus. This is followed by plasma nitriding the metal part surface and then depositing a Ti—Si—C—N nanocomposite coating.

A method of coating a metal part in a single physical vapor deposition device, comprising” (a) placing a metal part having a surface into a single physical vapor deposition device comprising a plasma-enhanced magnetron sputtering (PEMS) device; (b) filling said PEMS device with nitrogen and generating a nitrogen plasma comprising molecular and atomic nitrogen ions and plasma nitriding said metal part surface and forming a nitride layer in said metal part having a thickness of 5.0 μm to 30.0 μm; and (c) providing a Ti target in said PEMS device and introducing tetramethylene silane (TMS) or hexamethyldisilazane (HMDSN) and acetylene and depositing a Ti—Si—C—N nanocomposite coating comprising a layer having a thickness of 5.0 μm to 50.0 μm.

### BRIEF DESCRIPTION OF THE DRAWINGS

FIG. 1 is a schematic drawing of a PEMS plasma nitriding apparatus and process.

FIG. 2 is a schematic drawing of the PEMS apparatus now showing the deposition and coating of a Ti—Si—C—N nanocomposite coating.

FIG. 3 shows the substrate temperature measured as a function of the PEMS discharge current at different DC substrate bias voltages of −400 V, −600 V, and −1000 V, respectively.

FIG. 4 plots the thickness of the nitride layer on SS304 samples after PEMS nitriding and nitriding rate at different substrate temperatures for 2.0 hours.

FIG. 5 provides cross-sectional SEM micrographs of PEMS plasma nitrided SS304 stainless steel samples treated at different temperatures (a) 325° C., (b) 350° C., (c) 375° C., (d) 400° C., (e) 425° C., (f) 450° C., (g) 475° C., and (h) 525° C.

FIG. 6 provides XRD patterns of the PEMS plasma nitrided SS304 stainless steel samples treated at different temperatures.

FIG. 7 shows the hardness and Young's modulus of the PEMS plasma nitrided SS304 stainless steel surface treated at different temperatures.

FIG. 8 presents the sliding coefficient of friction (COF) and wear rate of the PEMS plasma nitrided SS304 stainless steel samples sliding against a 440C steel ball in 10W-30 lubricants under 2 N at 200 rpm after a 3200 meters travel distance.

FIG. 8b shows the water contact angle (WCA) of SS304 stainless steel surface in ambient air and mineral oil after PEMS plasma nitriding treatment at the indicated different temperatures after 2.0 hours.

FIG. 8c shows the appearance of water droplets and WCA of untreated and PEMS plasma nitrided SS304 stainless steel surface in ambient air and mineral oil.

FIG. 9 provides (a) Bright field (BF) and (b) dark field (DF) SEM images of the cross-section of a duplex Ti—Si—C—N nanocomposite coating and EDS mapping of the elements of (c) N, (d) Ti, (e) Si, and (f) C.

FIG. 10 provides (a) Bright field (BF) and (b) dark field (DF) SEM images of the cross-section of a duplex variable hardness Ti—Si—C—N nanocomposite coating and EDS mapping of the elements of (c) N, (d) Ti, (e) Si, and (f) C.

FIG. 11 presents frictional force, penetration depth, and optical image of the scratch track measured during a progressive scratch test of a duplex homogeneous Ti—Si—C—N nanocomposite coating deposited on SS304 stainless steel coupon. The normal load was increased from 0 N to 20 N and the scratch length was 5 mm.

FIG. 12 presents frictional force, penetration depth, and optical image of the scratch track measured during a progressive scratch test of a Ti—Si—C—N nanocomposite coating deposited on SS304 stainless steel coupon without PEMS plasma nitriding. The normal load was increased from 0 N to 20 N and the scratch length was 5 mm.

FIG. 13 provides a cross-sectional SEM image and EDS mapping of the N element of a Ti-6Al-4V sample treated by PEMS plasma nitriding at 780° C. with a substrate bias voltage of −1000 V for 2 hours.

FIG. 14 provides XRD patterns of untreated Ti-6Al-4V and after PEMS plasma nitriding at 780° C.

FIG. 15a shows the wear track profile of untreated Ti-6Al-4V sliding against a Al₂O₃ ball under 1 N at 100 rpm after 5000 test cycles.

FIG. 15b shows the wear track profile of PEMS plasma nitrided Ti-6Al-4V sliding against a Al₂O₃ ball under 1 N at 100 rpm after 5000 test cycles.

FIG. 16 shows a cross-sectional SEM image and EDS mappings of N and Nb element of C103 alloy after PEMS plasma nitriding at 800° C. at a substrate bias voltage of −1000 V for 2 hours.

### DETAILED DESCRIPTION

The present disclosure is directed at a duplex nanocomposite coating that is formed by nitriding and surface treatment of a metallic surface, followed by deposition of a Ti—Si—C—N nanocomposite coating layer, in a single physical vapor deposition device. A physical vapor deposition device is understood herein to be a device that converts target materials into gaseous atoms, molecules, and ionized species under vacuum and then condense these species onto a selected substrate as a coating. For example, the duplex coating is preferably conducted in a single plasma-enhanced magnetron sputtering (PEMS) apparatus. Accordingly, in the PEMS apparatus, there is now integration of both plasma nitriding treatment and nanocomposite coating deposition in the physical vapor deposition device, thereby providing both nitriding and coating. Plasma nitriding is reference to the formation of molecular and atomic nitrogen ions that diffuse into a metallic surface. Accordingly, it can be appreciated herein that the PEMS duplex coating technique is such that both PEMS plasma nitriding and later deposition of a nanocomposite coating layer can use/share plasma and process resources (the PEMS global discharge plasma) in the same system.

Duplex coating herein is therefore reference to a metallic surface layer having a surface diffused with nitrogen that is coated with the Ti—Si—C—N nanocomposite coating layer. One example of a plasma-enhanced magnetron sputtering apparatus suitable for use herein is described in the above referenced U.S. Publication 2024/0093351. Accordingly, the present invention can avoid the need to utilize different devices and process resources such as one device that provides plasma nitriding and another device that provides the physical vapor deposition procedure.

The metallic surface for coating herein preferably comprises a piston ring. Piston rings are commonly utilized to provide a seal between a piston and cylinder liner so that the engine combustion can achieve a desired pressure. Piston rings, which are steel-based, are therefore typically attached to the outer diameter of a piston in the internal combustion engine. The metallic surface for coating herein is contemplated to also include other metallic components, such as metal forming dies and die components, firearm components, and metal components utilized in the gas and oil industry. In addition, the metallic components include ferrous materials and are contemplated to include titanium alloys, nickel-chromium alloys, and niobium alloys.

The metallic surface herein may therefore now be treated by a combination of plasma nitriding with subsequent deposition of a Ti—Si—C—N nanocomposite coating layer to reduce the coefficient of friction, improve wear resistance, improve fatigue resistance, and provide relatively improved compatibility with lubricants. Within the single process physical vapor deposition device, such in a device offering plasma-enhanced magnetron sputtering, the nitriding may now first be applied prior to nanocomposite coating to provide improved mechanical support characteristics and fatigue resistance for the nanocomposite coating layer. In the case of ferrous materials, such nitriding herein is also preferably conducted at temperatures of less than or equal to 500° C.

The nitride layer so formed in the single PEMS device is contemplated to have a surface hardness of at or above 1250 HV0.1 (which applied a test force of 0.1 kgf). In addition, it is contemplated that the nitride layer herein may be compositionally graded with an increase in nitrogen content from a lower portion of the nitriding layer to an upper portion of the nitriding layer, wherein the hardness and elastic modulus is then contemplated to increase from the lower portion to the upper portion. In addition, it is contemplated that carbon may also be introduced with nitrogen during the nitriding step herein to produce a mixed nitrocarburizing layer. Overall, one now preferably avoids the need to utilize two separate process environments, namely one for nitriding and one for nanocomposite coating, which adds time and cost to coating production.

It is also worth noting that Ti—Si—C—N nanocomposite coatings on steel piston rings can on their own provide relatively reduced COF and relatively improved wear performance. However, the adhesion strength between the Ti—Si—C—N nanocomposite coating and the piston ring and the fatigue resistance of the coating are contemplated herein as lacking optimization due to the relatively large difference in the hardness and elastic modulus of the metallic ring surface and the nanocomposite coating. Namely, it is contemplated that the relatively softer steel piston ring does not provide sufficient mechanical support to an upper nanocomposite coating, particularly under conditions of relatively high friction, fatigue, and/or torque conditions. This lack of mechanical support is also contemplated to be relatively more pronounced when the thickness of the Ti—Si—C—N nanocomposite coating is greater than or equal to 50.0 μm.

As therefore noted herein, in the single physical vapor deposition device utilizing plasma enhanced magnetron sputtering, plasma nitriding treatment is now integrated with nanocomposite coating deposition. The lower nitride layer preferably has a thickness of 5.0 μm to 30.0 μm, including all individual values and increments therein. For example, the nitride layer, which is the result of plasma nitriding treatment, can have a thickness of 5.0 μm, 10.0 μm, 15.0 μm, 20.0 μm, 25.0 μm or 30 μm. This is then followed in the preferred single PEMS device with formation of the upper nanocomposite coating layer onto the nitride layer which upper layer comprises Ti—Si—C—N at a preferred thickness of 5.0 μm to 50.0 μm, including all individual values and increments therein. For example, the Ti—Si—C—N nanocomposite layer may have a thickness of 5.0 μm, 10.0 μm, 15.0 μm, 20.0 μm, 25.0 μm, 30.0 μm, 35.0 μm, 40.0 μm, 45.0 μm and 50.0 μm.

Preferably, the upper Ti—Si—C—N nanocomposite coating comprises: (1) titanium in the range of 35 to 49 atomic percent, including all individual values and increments therein; (3) silicon present in the range of 1 to 5 atomic percent, including all individual values and increments therein; (3) carbon in the range of 17 to 41 atomic percent, including all individual values and increments therein; and (4) nitrogen in the range of 19 to 35 atomic percent.

As may now be further appreciated from the above, the Ti—Si—C—N coating herein can preferably have a homogenous hardness through the thickness of such coating. In addition, the Ti—Si—C—N coating can have a relatively low hardness that can preferably increase from the upper coating down to the surface between the interface between the Ti—Si—C—N coating and the nitride layer. For example, the surface region of the Ti—Si—C—N coating may have a hardness in the range of 5.0 GPa to 10.0 GPa at an initial thickness of up to 5.0 μm and below 5.0 μm a hardness in the range of greater than 10.0 GPa to 30.0 GPa.

### Working Examples

### PEMS Plasma Nitriding

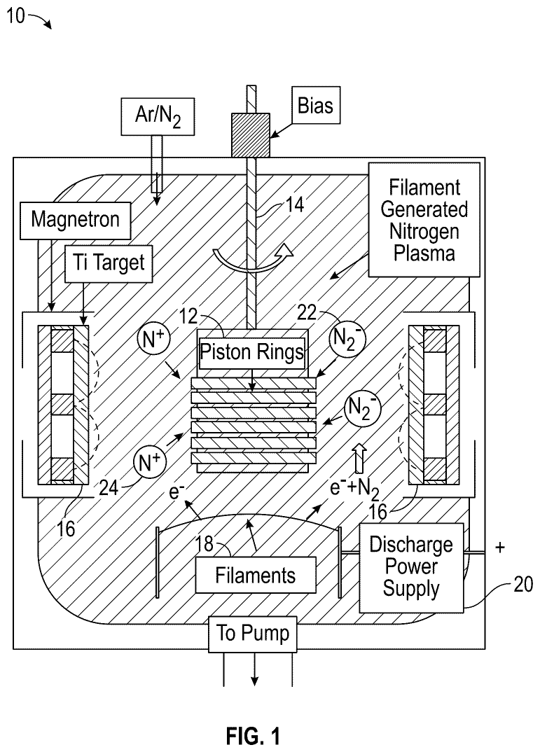

The substrates were mirror polished SS304 stainless steel coupons (25.4 mm×25.4 mm×3 mm) and steel piston rings. All substrates were cleaned in acetone and alcohol before being loaded into the PEMS chamber. As illustrated in FIG. 1, within the PEMS nitriding apparatus 10, the piston ring samples 12 were installed on a rotation substrate holder 14 and installed vertically between Ti targets 16. The chamber was pumped down to a base pressure below 3.0×10⁻⁴ Pa utilizing a diffusion pump at a baking temperature of 250° C. Tungsten (W) filaments 18 were installed in the chamber to generate a global discharge of plasma. The PEMS technique draws electrons from the hot filaments when electrons have gained enough energy to exceed the work function of the filaments. The electrons are accelerated by a discharge power supply 20 and collide with the neutral gas molecules and generate a relatively large number of gas ions through impact ionization. As a result, an independent global discharged plasma is generated in the entire chamber and around the metal parts. Prior to coating depositions, the substrates are preferably cleaned using an argon (Ar) global plasma generated by the hot filaments at a substrate bias voltage of −120 V. After plasma cleaning of the substrates, the chamber was back filled with nitrogen (N₂) to generate a global nitrogen plasma. During the ensuing nitriding process, molecular 22 and atomic nitrogen ions 24 are generated by impact ionization from electrons emitted from the hot filaments and attracted towards the substrate surface by a negative bias voltage. The nitriding rate and depth of the nitride layer are therefore controlled by the PEMS parameters, which preferably include a filament discharge current from 0.5 A to 30 A, the substrate bias voltage from 300 V to 1500 V, and processing time from 1 hour to 8 hours.

More generally, the plasma nitriding process can be preferably carried out in pure nitrogen or a mixture of N₂ and Ar at different gas flows. For example, 100% N₂, or 80% of N₂ and 20% Ar. The individual gas flow rate of N₂ and Ar can also be preferably varied from 20 sccm to 200 sccm, including all values and increments therein. A small fraction of hydrogen (H₂) up to 10% may also be added into the gas mixture. The working pressure of the chamber is preferably varied from 1 mTorr to 20 mTorr. The substrate bias voltage during nitriding may preferably be varied from −300 V to −1500 V in either DC or pulsed DC waveforms. The PEMS discharge current can preferably be varied from 0.5 A to 30 A.

It should also be noted that by controlling the PEMS discharge current and substrate bias voltage, different substrate temperatures can be achieved during the plasma nitriding process. The thickness and phase structure of the nitride layers may therefore be altered by such variation in PEMS discharge current, substrate bis voltage, substrate temperature and processing time, as disclosed further herein.

### Ti—Si—C—N Nanocomposite Coating Deposition

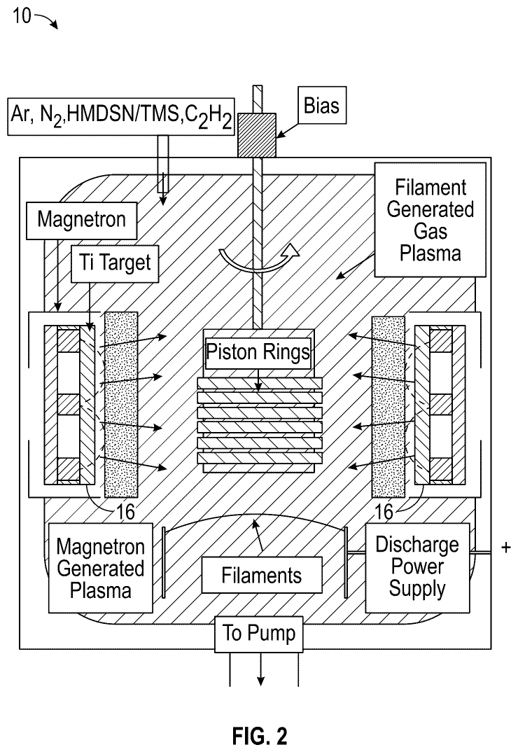

As illustrated in FIG. 2. after plasma nitriding in the PEMS environment noted above in FIG. 1, a Ti adhesion layer, preferably of 200 nm thickness, was first deposited by sputtering the Ti targets 16 in pure Ar. Then a TiN interlayer preferably of 200 nm to 300 nm thickness, was deposited by introducing N₂ into the chamber. This is followed by sputtering the Ti targets in a mixture of Ar, N₂ and tetramethylsilane (TMS) or hexamethyldisilazine (HMDSN) and acetylene (C₂H₂). During coating depositions, the Ti targets were powered up by pulsed DC or high power impulse magnetron sputtering (HiPIMS) with a constant average power of 4 kW. The Ar and N₂ flow rates were preferably maintained at 100 sccm and 50 sccm, respectively. The working pressure during the depositions was preferably 0.3 Pa. The hot filament discharge current may be varied between 0.5 A to 5 A. A −60 V DC bias voltage was preferably applied to the substrates during depositions. To deposit a variable hardness Ti—Si—C—N coating, the TMS and C₂H₂ gas flow rates were increased from 0 sccm to 6 sccm and 0 to 40 sccm, respectively, from the interface between the substrate and to the outer surface of the coating.

### Thickness and Structure of Plasma Nitrided Layers on a Steel Substrate

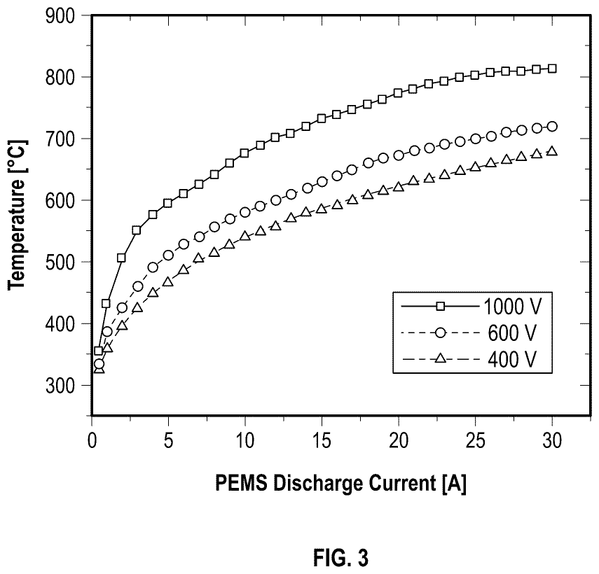

As noted above, it was observed that the thickness of the PEMS nitrided layer was affected by the substrate temperature which is determined by the PEMS discharge current and the substrate bias voltage. FIG. 3 shows the substrate temperature measured as a function of the PEMS discharge current at different DC substrate bias voltages of −400 V, −600 V, and −1000 V, respectively.

Table 1 summarizes the identified preferred process parameters and the nitrided layer thickness of a series of SS304 stainless steel samples treated by PEMS plasma nitriding at different PEMS discharge currents from 0.5 A to 10.5 A at a −400 V substrate bias voltage. The increase in the PEMS discharge current leads to an increase in the substrate temperature from 325° C. to 550°

TABLE 1
Process Parameters of The PEMS Nitriding of SS304 Stainless Steel Samples

| | PEMS Discharge | N₂ | Bias | | | | Nitrided layer | Nitriding |
|---|---|---|---|---|---|---|---|---|
| | Current | flow | Voltage | P | Time | Temperature | Thickness | Rate |
| ID | [A] | [sccm] | [V] | [mTorr] | [hr] | [° C.] | [nm] | [nm/min] |
| N19 | 0.5 | 110 | 400 | 1 | 2 | 325 | 330 | 2.75 |
| N18 | 1.0 | 110 | 400 | 1 | 2 | 350 | 640 | 5.3 |
| N20 | 1.5 | 110 | 400 | 1 | 2 | 375 | 1060 | 8.8 |
| N17 | 2.5 | 110 | 400 | 1 | 2 | 400 | 2900 | 24.2 |
| N21 | 3 | 110 | 400 | 1 | 2 | 425 | 4500 | 37.5 |
| N22 | 4 | 110 | 400 | 1 | 2 | 450 | 5500 | 41.7 |
| N24 | 5 | 110 | 400 | 1 | 2 | 475 | 8000 | 66.7 |
| N25 | 6.8 | 110 | 400 | 1 | 2 | 500 | 14000 | 116 |
| N26 | 8.5 | 110 | 400 | 1 | 2 | 525 | 20000 | 166 |
| N30 | 10.5 | 110 | 400 | 1 | 2 | 550 | 30000 | 250 |

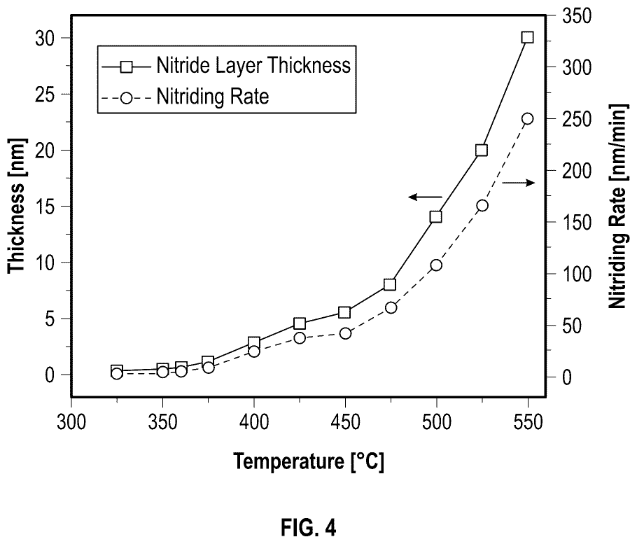

FIG. 4 next plots the thickness and nitriding rate of the nitrided layer on SS304 stainless steel samples after PEMS nitriding at different substrate temperatures for 2 hours. The samples showed a nitrided layer thickness less than 1060 nm when the substrate temperature was less than 375° C. The nitrided layer thickness increased from 1060 nm to 8000 nm as the temperature increased from 375° C. to 475° C. The thickness of the nitrided layer increased rapidly when the substrate temperature was above 475° C. The thickness of the nitrided layer increased to 30 μm after PEMS nitriding at 550° C. for 2 hours.

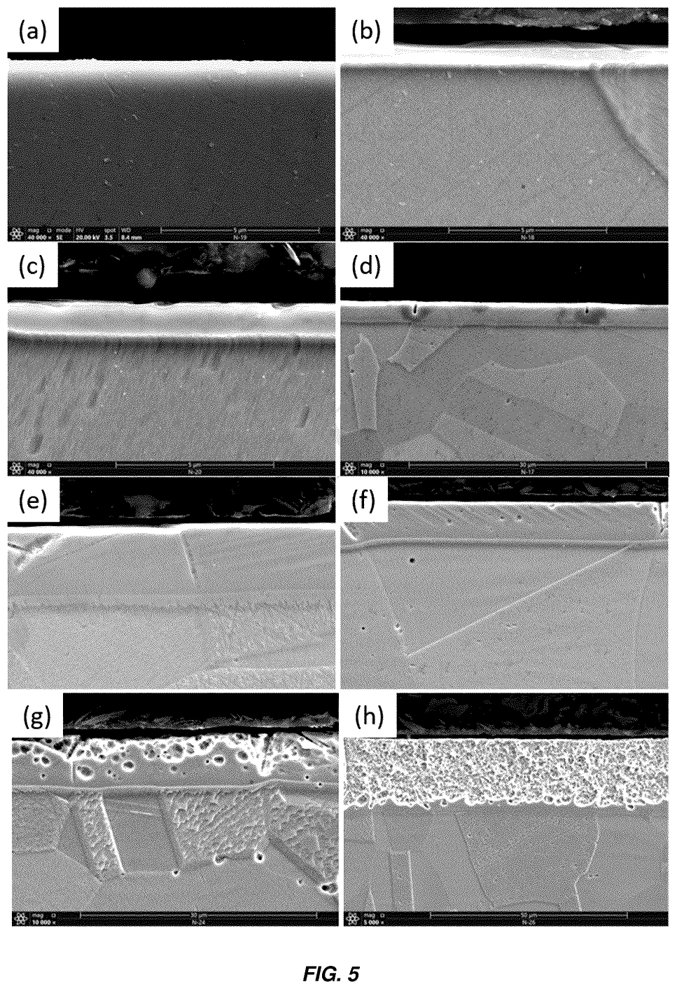

The cross-sectional microstructure of the PEMS plasma nitride SS304 stainless steel samples was examined using scanning electron microscopy (SEM) (Thermo Scientific Quattro S). FIG. 5 provides cross-sectional SEM micrographs of PEMS plasma nitrided SS304 stainless steel samples treated at different temperatures (a) 325° C., (b) 350° C., (c) 375° C., (d) 400° C., (e) 425° C., (f) 450° C., (g) 475° C., and (h) 525° C. The samples were etched using Viella's reagent. A 330 nm and 640 nm nitrided layer were observed on samples nitrided at 325° C. and 350° C., respectively. As the temperature increased from 375° C. to 475° C., the thickness of the nitride layer gradually increased from 1 μm to 8 μm. Further increasing the temperature to 525° C., the thickness of the nitride layer increased significantly to 20 μm. Dense interfaces were observed between the nitride layers and steel substrate for all processing temperatures. The nitrided layers formed at temperatures below 475° C. exhibited dense structure and strong resistance to chemical etching. In contrast, the nitride layers formed at temperatures above 475° C. exhibited a degradation of the corrosion resistance to chemical etching as shown in FIG. 5 for micrographs (g) and (h). The degraded corrosion resistance of the nitrided samples at high temperatures (e.g. 525° C.) is due to the outward diffusion of Cr from SS304 stainless steel.

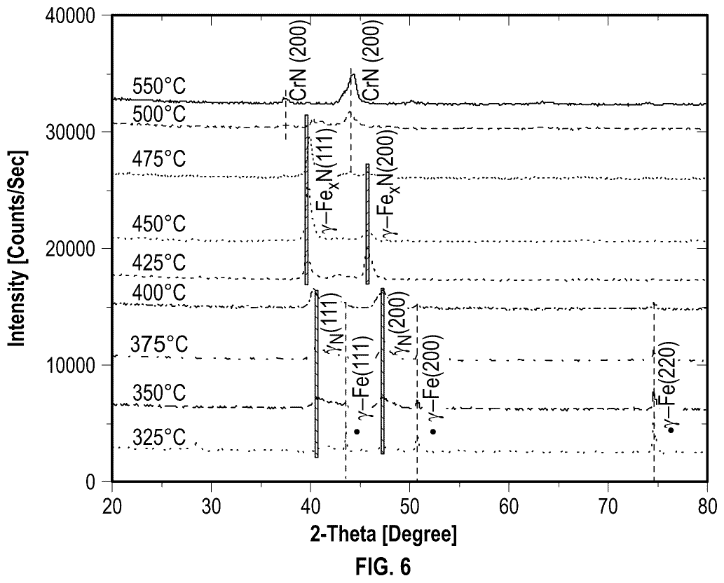

The phase structure of the PEMS plasma nitrided SS304 stainless steel samples was studied using X-ray diffraction (XRD) (Panalytical Empyrean X-Ray Diffractometer) in the conventional theta-two theta configuration. FIG. 6 shows the XRD patterns of the PEMS plasma nitrided SS304 stainless steel samples treated at different temperatures. The results showed that the process temperature strongly affected the phase structure of the nitrided layers. At 325° C., strong austinite γ-Fe (111) and (200) diffraction peaks from bulk SS304 stainless steel and weak γ_{N} (111) and γ_{N} (200) associated to the expended austinite phase were observed. The peaks of the γ_{N} phase exhibited low intensity due to its small thickness (330 nm) at 325° C. As the temperature increased from 325° C. to 400° C., the intensity of the γ-Fe (111) and (200) diffraction peaks gradually decreased accompanied with an increase in the intensity of the γ_{N} phase. This change is correlated to the increased thickness of the γ_{N} layer. In addition, the peak position of the γ_{N} phase gradually shifted towards lower diffraction angles as the temperature increased, which indicates an increase in the nitrogen content in the austinite phase that resulted in lattice expansion.

As the temperature increased to the range from 425° C. to 475° C., strong diffraction peaks associated to the γ-FeₓN nitrided phase were revealed in the XRD patterns. A small (200) diffraction peak of CrN phase were revealed in the sample treated at 475° C., which indicates the occurrence of the outward diffusion of Cr and formation of CrN on the surface. As the temperature further increased to 500° C. and above, the main phase on the outer surface is CrN. The results suggest that outward diffusion of Cr occurred from 475° C. and became dominate above 500° C. The depletion of Cr from the bulk of substrate degrades the corrosion resistance of SS304 steel, as confirmed from the SEM images shown in FIG. 5h.

### Mechanical and Tribological Properties of the Plasma Nitrided Layer

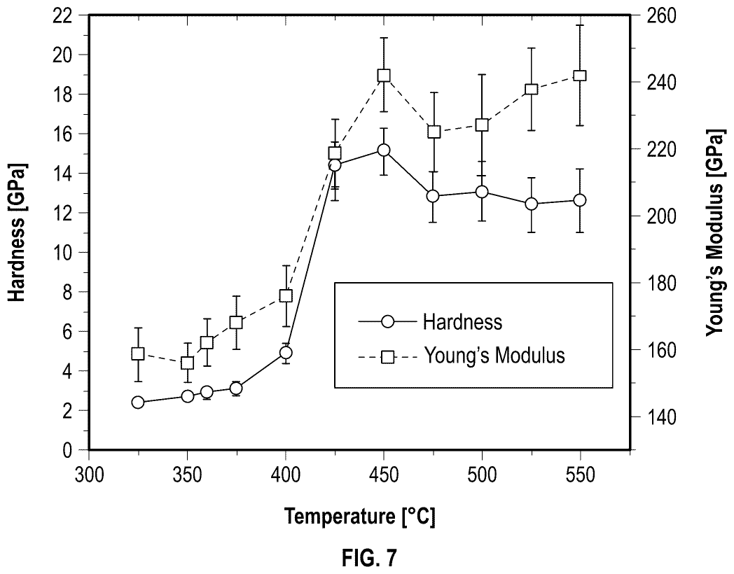

The hardness and Young's modulus of the PEMS plasma nitrided SS304 stainless steel samples were measured using a microhardness tester (MCT, Anton Paar) equipped with a diamond vicker indenter by averaging 12 effective measurements. The indentation depth was less than 10% of the nitrided layer thickness to minimize the substrate effect. FIG. 7 shows the hardness and Young's modulus of the PEMS plasma nitrided SS304 stainless steel surface treated at different temperatures. The untreated SS304 stainless steel typically exhibits a hardness value of 2.0 GPa. The hardness of the SS304 steel surface slightly increased from 2.4 GPa to 4.9 GPa after PEMS nitriding from 325° C. to 400° C. As the temperature increased to 425° C. and 450° C., a great increase in the surface hardness to 14.4 GPa and 15 GPa was measured. The increase in the surface hardness is attributed to the formation of the nitrided phase and the increased thickness of the nitrided layer, as shown in FIGS. 5 and 6. The surface hardness of the nitrided samples slightly decreased but remained at relatively high values in the range of 12.5 to 13 GPa as the temperature was further increased from 450° C. to 550° C., which correlates to the formation of a CrN phase on the surface. By correlating the hardness and the phase structure of the nitrided layers, it can be observed that the relatively largest improvement in the surface hardness of PEMS nitrided steel occurred at 425° C. and above, at which the γ-FeₓN nitrided phase was formed.

The wear behavior of the PEMS plasma nitrided SS304 stainless steel samples was evaluated using a ball on disk microtribometer in full-formulated SAE 10W-30 engine lubricant at a room temperature of 22±2° C. and a relative humidity of 25±5%. The lubricant's kinematic viscosities are 63 mm²/s at 40° C. and 10.5 mm²/s at 100° C. No surfactants or dispersant agents were added in the lubricant. The tests were carried out along a circular track of 10 mm diameter under a load of 2 N (a Hertzian contact stress about 0.54 GPa) and at a linear sliding speed of 10.5 cm/sec, for a sliding distance of 3200 m. A 440C steel ball with a diameter of 6 mm was used as the counterpart. All experiments were repeated three times to assure consistency of results. After the wear tests, the wear volume of the coatings was measured by obtaining a 2-dimensional cross-sectional profile of the wear track using a Dektak® surface profilometer to calculate the wear rate.

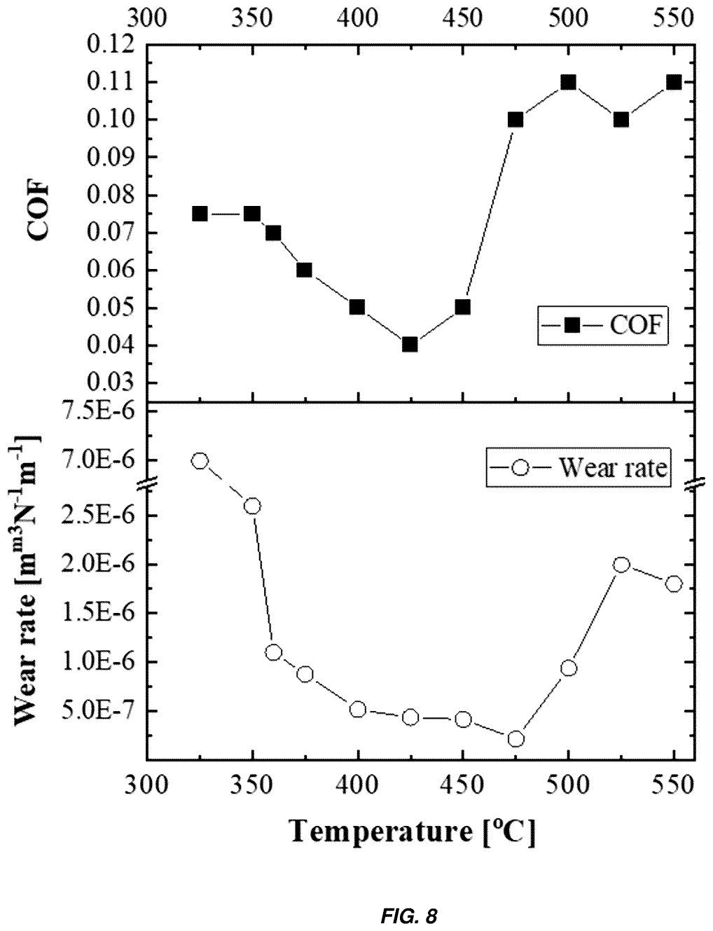

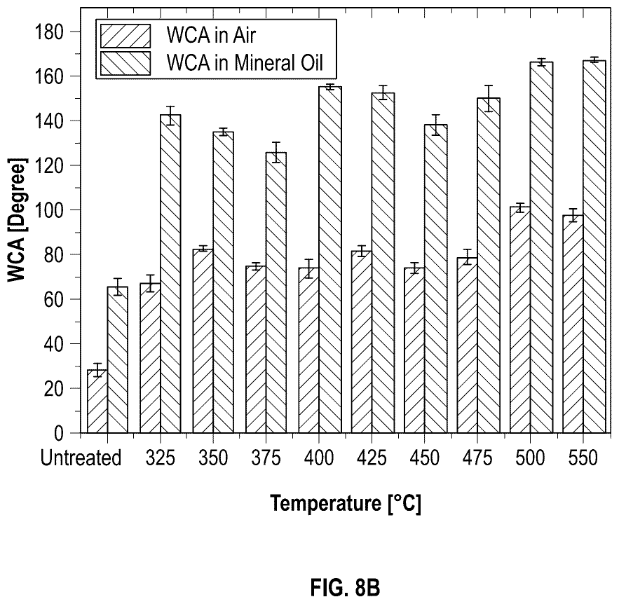

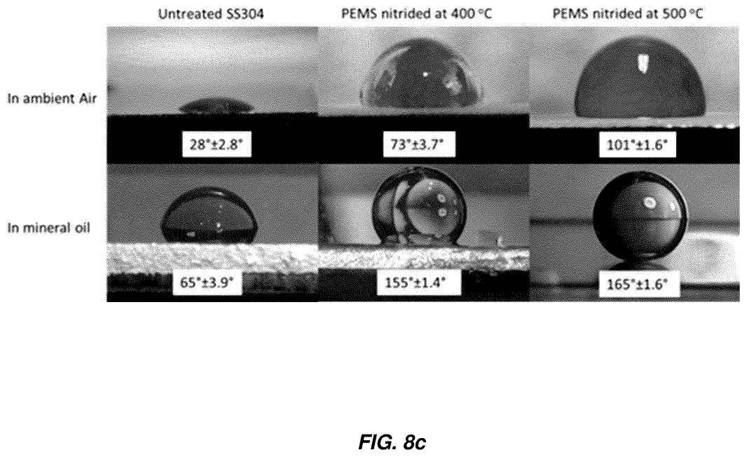

FIG. 8 presents the mean sliding coefficient of friction (COF) and wear rate of the PEMS plasma nitrided SS304 stainless steel samples sliding against a 440C steel ball in 10W-30 lubricants. Typically, a COF of 0.12 and a wear rate of 9×10⁻⁶ mm³N⁻¹m⁻¹ were measured for uncoated SS304 samples. All PEMS nitrided SS304 samples showed reduced COF and wear rates sliding against a 440C ball in 10W-30. The samples nitrided at 325° C. exhibited a COF of 0.075 and a relatively high wear rate of 7×10⁻⁶ mm³N⁻¹m⁻¹. As the PEMS nitriding temperature increased, the COF of the nitrided surfaces decreased rapidly and reached the lowest value of 0.04 at 425° C. and gradually increased back to 0.1-0.11 when the nitriding temperature was above 475° C. The wear rate of the nitrided surfaces greatly reduced to the range of 2×10⁻⁷ mm³N⁻¹m⁻¹ to 4×10⁻⁷ mm³N⁻¹m⁻¹ when the nitriding temperature increased to the range from 400° C. to 475° C. due to the increased thickness and hardness of the nitrided layer. However, when CrN formed on the surface at above 475° C., both the COF and wear rate of the surface increased.

Hydrophobicity of a PEMS nitride steel surface was also evaluated. The SS304 stainless steel surface showed hydrophobic behavior after PEMS nitriding treatment. FIG. 8b shows the water contact angle (WCA) of SS304 stainless steel surface in ambient air and mineral oil after PEMS plasma nitriding treatment at different temperatures for 2 hours. FIG. 8c shows several examples of the appearance of the water droplets and WCA of untreated and PEMS plasma nitrided SS304 stainless steel surfaces in ambient air and mineral oil.

The untreated SS304 steel surface is hydrophilic which showed a low WCA of 28° and 650 in ambient air and mineral oil, respectively. The WCA of SS304 steel surface increased to the range of 670 to 850 in ambient air and to the range of 1300 to 1500 in mineral oil after PEMS nitriding treatment between 325° C. to 475° C. for 2 hours. As the PEMS nitriding temperature increased to 500° C. and above, the WCA of SS304 steel surface further increased to 101° in ambient air and 165° in mineral oil.

### Structure and Adhesion of Duplex Nanocomposite Coatings (Homogenous and Variable Hardness Ti—Si—C—N)

After PEMS nitriding, a Ti—Si—C—N coating can be deposited onto the nitrided layer to form the duplex nanocomposite coating. Either a homogeneous Ti—Si—C—N or a variable hardness (VH) Ti—Si—C—N nanocomposite coating can be deposited.

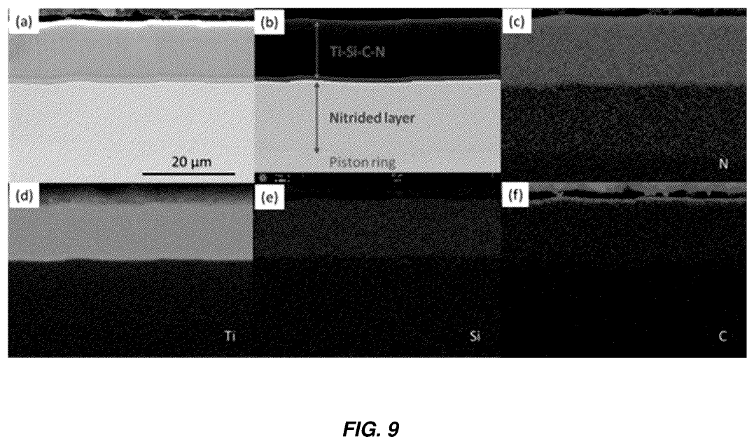

FIG. 9 shows the cross-sectional microstructure and EDS mapping of the elements of a duplex homogeneous Ti—Si—C—N coating deposited on piston rings. The duplex coating comprises a dense nitrided layer on the ring surface and a homogeneous Ti—Si—C—N coating on the top. The Ti—Si—C—N layer was deposited by following the procedures described in U.S. Pat. No. 9,523,146. The thickness of the homogeneous Ti—Si—C—N coating and the nitrided layer is about 15 μm and 20 μm, respectively. The nitrided layer is clearly identified from the dark field (DF) SEM image and EDS mapping of N (FIG. 9, image b and image c). The interfaces between the nitrided layer and bulk of the substrate, and between the Ti—Si—C—N coating and the nitrided layer are dense without porosities.

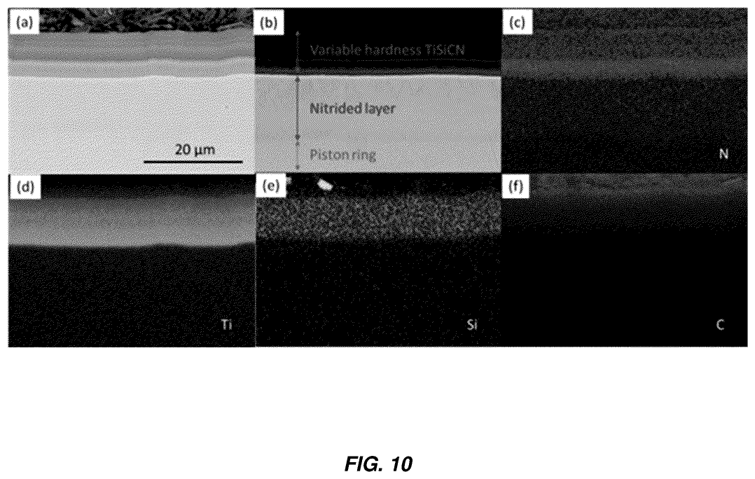

FIG. 10 shows the cross-sectional microstructure and EDS mapping of the elements of a duplex VH Ti—Si—C—N coating deposited on piston rings. The VH Ti—Si—C—N layer was deposited by following the procedures described in U.S. Publication No. 2024/0093351 A1. The thickness of the VH Ti—Si—C—N coating and the nitrided layer is about 9 μm and 15 μm, respectively. The nitrided layer is clearly identified from the dark field (DF) SEM image and EDS mapping of N (FIG. 10, image b and c).

The adhesion of the duplex homogeneous Ti—Si—C—N nanocomposite coating and a Ti—Si—C—N nanocomposite coating without PEMS nitriding treatment deposited on SS304 stainless steel coupons was evaluated by a scratch tester (MCT, Anton Paar) using a conical Rockwell-C diamond tip with a spherical tip radius of 100 m and 120° C. apex angle. The normal load was progressively increased from 0 to 20 N. The scratch length was 5 mm. The frictional force was recorded to identify the critical load of the scratch test. The penetration depth was recorded to assure that the scratch test has penetrated the thickness of the Ti—Si—C—N coating. After the test, the scratch track was examined using an optical microscope to observe coating failure morphology.

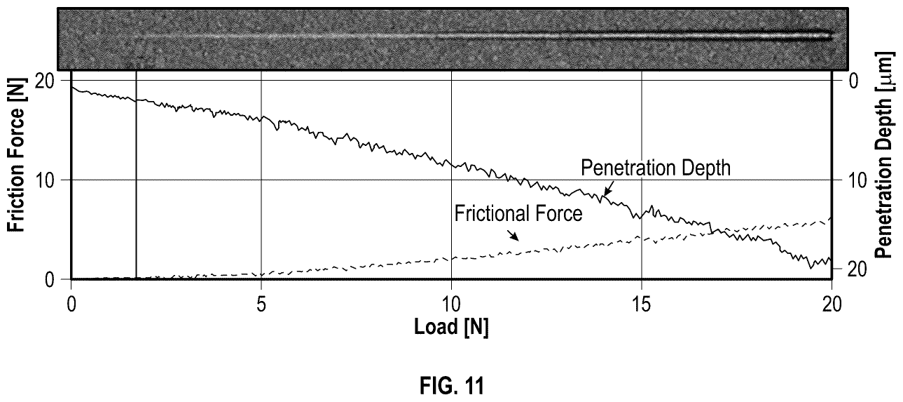

FIG. 11 presents the frictional force, penetration depth, and optical image of the scratch track measured during the scratch test for duplex homogeneous Ti—Si—C—N nanocomposite coating. The duplex coating exhibited excellent adhesion strength. The frictional force gradually increased as the normal load increased. The frictional force exhibited very small fluctuation with increasing normal load, which indicates no substrate material was exposed. The maximum penetration depth of the diamond tip reached 20 μm at the maximum load, which exceeded the thickness of the coating (15 μm). No failure and delamination of the coating were observed along the scratch track from the optical image.

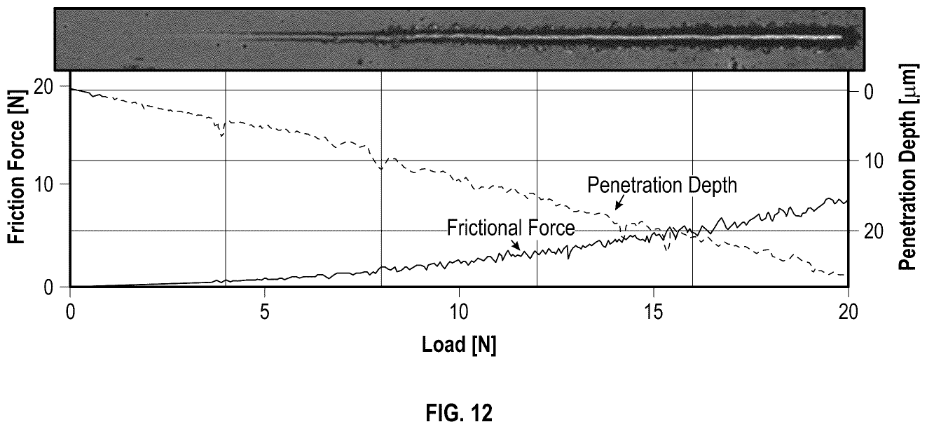

FIG. 12 presents the frictional force, penetration depth, and optical image of the scratch track measured during the scratch test for a prior art Ti—Si—C—N nanocomposite coating deposited without using the PEMS duplex method herein. The frictional force gradually increased as the normal load increased. The frictional force exhibited relatively larger fluctuation with increasing normal load as compared to the duplex homogeneous Ti—Si—C—N nanocomposite coating (FIG. 11). The maximum penetration depth of the diamond tip reached 28 μm at the maximum load, which indicates a significant level of plastic deformation of the SS304 substrate without the PEMS plasma nitriding treatment. The first chipping of the coating along the scratch track was observed at a critical load of 8 N in the optical image. The coating delamination within the scratch track was also revealed at the end of the scratch test. These results indicate that the duplex Ti—Si—C—N coating showed greatly improved adhesion strength on steel compared to the Ti—Si—C—N coating deposited without the PEMS plasma nitriding treatment.

### PEMS Plasma Nitriding of Ti and Nb Alloys

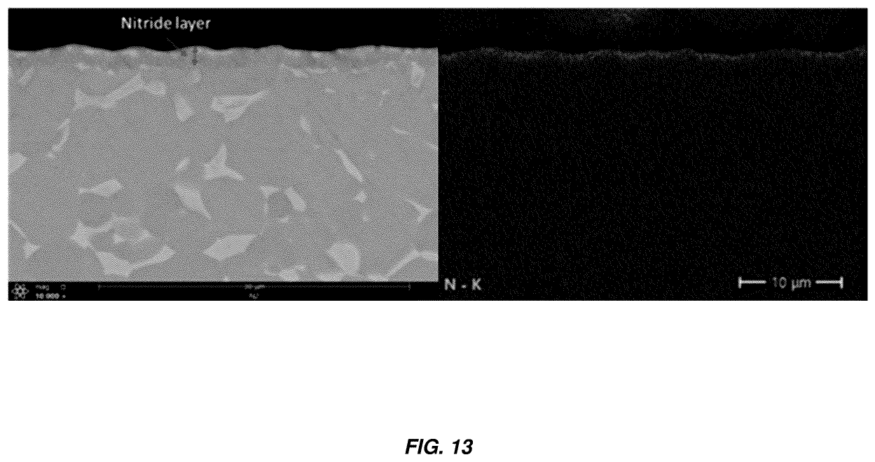

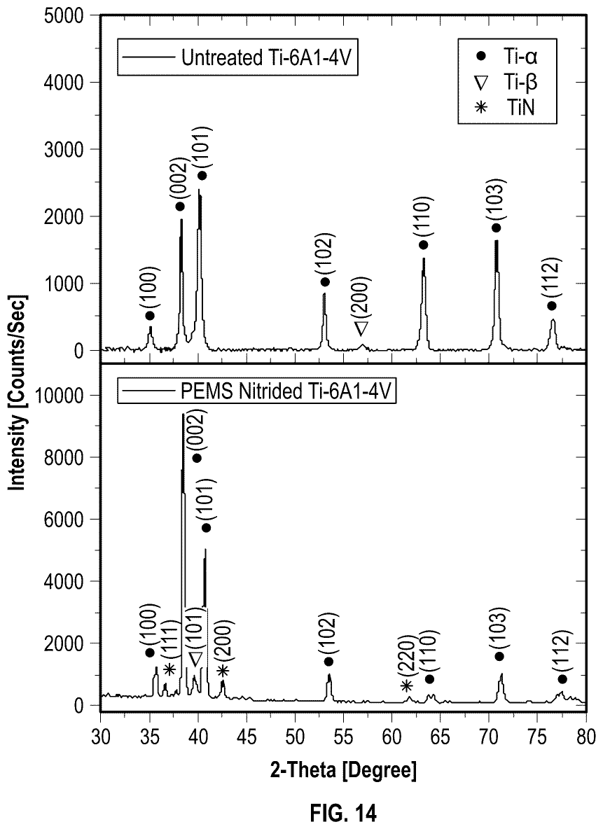

FIG. 13 shows a cross-sectional SEM image and EDS mapping of the N element of a Ti-6Al-4V alloy after PEMS plasma nitriding at 780° C. at a substrate bias voltage of −1000 V for 2 hours. A nitrided layer with thickness of 2 μm was formed on the surface. FIG. 14 shows a comparison of the XRD patterns of untreated Ti-6Al-4V alloy and after PEMS plasma nitrided at 780° C. The formation of cubic TiN phase was revealed in the PEMS plasma nitrided Ti-6Al-4V sample. The hardness of Ti-6Al-4V surface increased from 0.3 GPa to 18 GPa after PEMS nitriding due to the formation of the TiN layer.

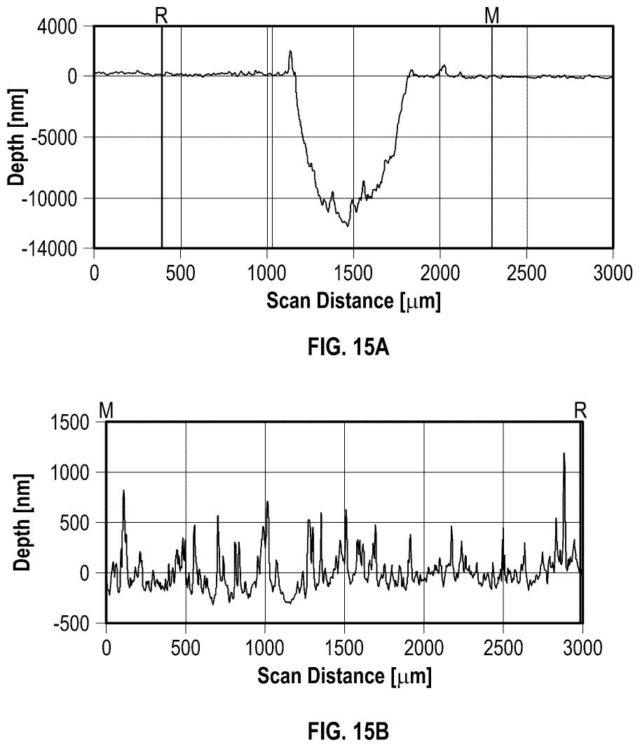

In addition, the wear resistance of Ti-6Al-4V was greatly improved after PEMS plasma nitriding. FIGS. 15a and 15b shows a comparison of the profile of the wear track measured on untreated and PEMS plasma nitrided Ti-6Al-4V samples after sliding against an Al₂O₃ ball under 1 N at 100 rpm for 5000 test cycles. The untreated Ti-6Al-4V sample (FIG. 15a) exhibited a wear depth of 11 μm after the wear test. In contrast, the PEMS plasma nitrided Ti-6Al-4V sample (FIG. 15b) showed no wear on the surface.

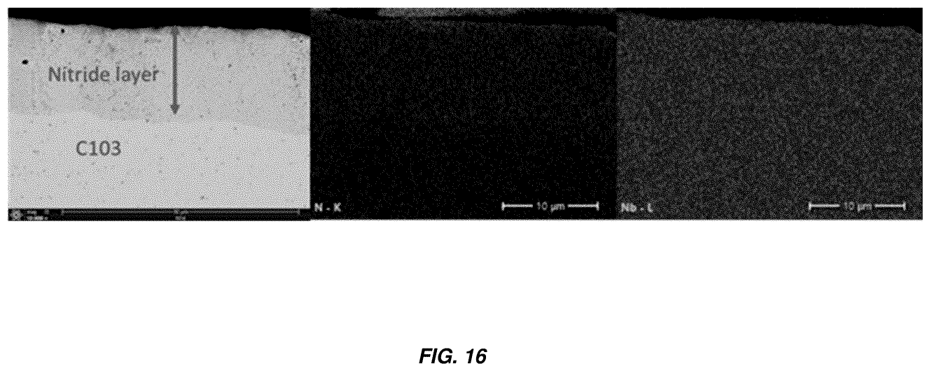

The PEMS plasma nitriding technique has also been used to plasma nitriding C103 Nb alloy. FIG. 16 shows a cross-sectional SEM image and EDS mappings of N and Nb element of C103 alloy after PEMS plasma nitriding at 800° C. at a substrate bias voltage of −1000 V for 2 hours. A 20 μm nitrided layer has been developed on C103 Nb alloy surface as shown in the SEM image and EDS mapping.

What is claimed is:

1. A method of coating a metal part in a single physical vapor deposition device, comprising:
a. placing a metal part having a surface into a single physical vapor deposition device comprising a plasma-enhanced magnetron sputtering (PEMS) apparatus;
b. plasma nitriding said metal part surface; and
c. depositing a Ti—Si—C—N nanocomposite coating.

2. The method of claim 1, wherein nitriding of said metal part surface comprises filling said PEMS device with nitrogen and generating a nitrogen plasma comprising molecular and atomic nitrogen ions and providing a negative bis voltage to said metal part and drawing said molecular and atomic nitrogen ions towards said metal part surface.

3. The method of claim 1, wherein said step of deposition a Ti—Si—C—N nanocomposite coating comprises providing a Ti target in said PEMS device and forming a Ti adhesion layer followed by forming a TiN interlayer and then forming a Ti—Si—C—N coating layer.

4. The method of claim 1, wherein said nitriding comprises forming a nitride layer in said metal part at a thickness of 5.0 μm to 30.0 μm.

5. The method of claim 1, wherein said deposit of Ti—Si—C—N comprises a layer having a thickness of 5.0 μm to 50.0 μm.

6. The method of claim 1, wherein said Ti—Si—C—N nanocomposite coating comprises Ti in the range of 35 to 49 atomic percent, Si in the range of 1 to 5 atomic percent, carbon in the range of 17 to 41 atomic percent and nitrogen in the range of 19 to 35 atomic percent.

7. The method of claim 1, wherein said Ti—Si—C—N nanocomposite coating has a relative low hardness that increases from an upper portion of said coating to a lower portion of said coating.

8. The method of claim 5, wherein said Ti—Si—C—N nanocomposite coating has a hardness of 5.0 GPa to 10.0 GPa at an initial thickness of up to 5.0 μm and below 5.0 μm a hardness in the range of greater than 10.0 GPa to 30.0 GPa.

9. The method of claim 1, wherein plasma nitriding is carried out at a temperature of less than or equal to 500° C.

10. The method of claim 1, wherein said metal part comprises a piston ring, a metal forming die, a metal component part, titanium alloy or niobium alloy.

11. A method of coating a metal part in a single physical vapor deposition device, comprising:
a. placing a metal part having a surface into a single physical vapor deposition device comprising a plasma-enhanced magnetron sputtering (PEMS) device;
b. filling said PEMS device with nitrogen and generating a nitrogen plasma comprising molecular and atomic nitrogen ions and plasma nitriding said metal part surface and forming a nitride layer in said metal part having a thickness of 5.0 μm to 30.0 μm; and
c. providing a Ti target in said PEMS device and introducing tetramethylene silane (TMS) or hexamethyldisilazane (HMDSN) and acetylene and depositing a Ti—Si—C—N nanocomposite coating comprising a layer having a thickness of 5.0 μm to 50.0 μm.

12. The method of claim 11, wherein said Ti—Si—C—N nanocomposite coating comprises Ti in the range of 35 to 49 atomic percent, Si in the range of 1 to 5 atomic percent, carbon in the range of 17 to 41 atomic percent and nitrogen in the range of 19 to 35 atomic percent.

13. The method of claim 11, wherein said Ti—Si—C—N nanocomposite coating has a relative low hardness that increases from an upper portion of said coating to a lower portion of said coating.

14. The method of claim 13, wherein said Ti—Si—C—N nanocomposite coating has a hardness of 5.0 GPa to 10.0 GPa at an initial thickness of up to 5.0 μm and below 5.0 μm a hardness in the range of greater than 10.0 GPa to 30.0 GPa.

15. The method of claim 11, wherein plasma nitriding is carried out at a temperature of less than or equal to 500° C.

16. The method of claim 11, wherein said nitriding is carried out at a nitrogen gas flow in the range of 20 sccm to 200 sccm.

17. The method of claim 1, wherein said metal part comprises a piston ring, a metal forming die, a metal component part, titanium alloy or niobium alloy.

18. The method of claim 11, wherein said metal part comprises a piston ring, a metal forming die, a metal component part, titanium alloy or niobium alloy.
